(19) United States
(12) Patent Application Publication
(10) Pub. No.: US 2025/0218965 A1
(43) Pub. Date: Jul. 3, 2025

(54) SELF ALIGNMENT STRUCTURES FOR INTERCONNECT BRIDGES

(71) Applicant: Intel Corporation, Santa Clara, CA (US)

(72) Inventors: Brandon C. MARIN, Gilbert, AZ (US); Jeremy D. ECTON, Gilbert, AZ (US); Srinivas PIETAMBARAM, Chandler, AZ (US); Gang DUAN, Chandler, AZ (US)

(21) Appl. No.: 18/399,428

(22) Filed: Dec. 28, 2023

(51) Int. Cl. H01L 23/538; H01L 21/48; H01L 23/00; H01L 23/498; H01L 25/065

(52) U.S. Cl. CPC H01L 23/5386; H01L 21/4857; H01L 23/49811; H01L 23/5383; H01L 25/0655; H01L 24/14; H01L 24/16; H01L 2224/1403; H01L 2224/14177; H01L 2224/16227

(57) ABSTRACT

Assemblies that include package substrates and semiconductor chips are provided. The package substrates include interconnect bridges having through-bridge vias. The assemblies also include alignment features and receiving cavities.

### FIELD

Descriptions are generally related to semiconductor manufacture, and more particular descriptions are related to packaging semiconductor chips and interconnect bridges embedded in package substrates for semiconductor chips.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

High performance computing (HPC) applications, such as for example, artificial intelligence (AI) inferencing and chat generative pre-trained transformer (ChatGPT), are driving a significant package form-factor increase. Proposals for computing systems for HPC applications include integrating six times a silicon reticule size and more than 16 high bandwidth memory (HBM) units into a package. HBM can consist of stacks of dynamic random access memory (DRAM) dies. Semiconductor chip package assemblies that include multiple semiconductor chips, such as heterogeneous architectures, can include interconnect bridges, such as, for example embedded multi-die interconnect bridges (EMIBs) and/or EMIBs having through-bridge vias (EMIB-T) structures in the package. Interconnect bridges can provide interconnections between semiconductor chips within a package and packaged chips that include interconnect bridges are sometimes referred to as 2.5D architectures.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention. Additionally, features are not necessarily illustrated relatively to scale due in part to the small sizes of some features and the desire for clarity of explanation in the figures.

FIGS. 1A-1B provide semiconductor chip package assemblies comprising an interconnect bridge and alignment features.

FIGS. 2A-2B show additional semiconductor chip package assemblies that have an interconnect bridge and alignment features.

FIGS. 3A-3C illustrate a method for manufacturing a semiconductor chip package assembly that includes an interconnect bridge.

FIGS. 4A-4C illustrate an additional method for manufacturing a semiconductor chip package assembly that includes an interconnect bridge.

FIG. 5 shows an exemplary multi-chip package in which the package incorporates interconnect bridges.

FIG. 6 provides an exemplary computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation of the invention. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as physical operations. Physical operations can be performed by semiconductor processing equipment. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Various components described can be a means for performing the operations or functions described. Each component described can include software, hardware, or a combination of these. Some components can be implemented as software modules, hardware modules, special-purpose hardware (for example, application specific hardware, application specific integrated circuits (ASICs), digital signal processors (DSPs), etc.), embedded controllers, or hardwired circuitry). Other components can be semiconductor processing and/or testing equipment that is able to perform physical operations such as, for example, lithography, material deposition (for example, chemical vapor deposition, atomic layer deposition, and/or sputtering), chemical mechanical polishing, and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, and/or semiconductor chip are interchangeable and refer to a semiconductor device comprising integrated circuits.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include conducting through-silicon vias (TSVs) that traverse the semiconductor chip device region. Semiconductor devices that have conducting TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-K dielectrics, SiO₂, silicon nitride (SiN), silicon carbide (SiC), and/or silicon carbonitride (SiCN). Low-K dielectrics include for example, fluorine-doped SiO₂, carbon-doped SiO₂, porous SiO₂, porous carbon-doped SiO₂, combinations for the foregoing, and also these materials with airgaps. Dielectric layers that include conductive features can be intermetal dielectric (ILD) features.

The terms “package,” “packaging,” “IC package,” or “chip package,” “microelectronics package,” or “semiconductor chip package” are interchangeable and generally refer to an enclosed carrier of one or more dies, in which the dies are attached to a package substrate and encapsulated. The package substrate provides electrical interconnects between the die(s) and other dies and/or a motherboard or other printed circuit board for I/O (input/output) communication and power delivery. A package with multiple dies can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass materials.

In further examples of a package substrate core, the substrate core is a glass core comprising a solid amorphous glass material. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, exemplary solid amorphous glass substrate cores can be considered to have a rectangular prism volume. The rectangular prism volume can contain vias that have been filled with one or more different materials. A material in a via can be a conducting metal such as copper. Exemplary solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example, the substrate core can be 10 mm by 10 mm up to 250 mm by 250 mm in two dimensions, but substrate cores do not necessarily have to have the same value in both dimensions.

A package substrate can include one or more interconnect bridges. The interconnect bridge can be partially, fully, or not embedded into the package substrate. An interconnect bridge provides interconnects between chips that are housed on the package substrate. The interconnects can be for I/O between the chips. Some interconnect bridges, such as ones that have conductive through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The bridge can comprise, for example, a silicon substrate, a silicon-on-insulator substrate, a float glass substrate, a borosilicate glass substrate, a silicon dioxide substrate, and/or a silicon nitride substrate. The substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The bridge can also be a coreless substrate comprised of a plurality of dielectric layers. The dielectric layers can be, for example, die backside film (DBF), an epoxy film, a B-stage epoxy film, or other dielectric material. Other materials are possible.

For packages that include interconnect bridges, the pitch in the interconnect bridge region for first level interconnects (FLIs) assemblies can be less than the pitch for other regions of the FLI assembly. The pitch in the interconnect bridge region can be, for example, less than or equal to 25 μm. A low regression bump thickness variation (rBTV) can be more difficult to obtain in mixed pitch systems where there are pitches are less than or equal to 25 μm. A larger rBTV can negatively impact package assembly yields.

For packages where bump pitches are less than or equal to 25 μm, chip gap height (CGH) control can be more difficult. Tighter bump pitches mean that the pad sizes to apply solder will be smaller also. Forming healthy FLIs can be more difficult at smaller pitches and assembly yields can suffer. Yield impacts are magnified as packages integrate larger numbers of chips. Alignment of the FLI interconnect regions of an interconnect bridge with the FLI interconnect regions of the package substrate is important to forming healthy FLIs.

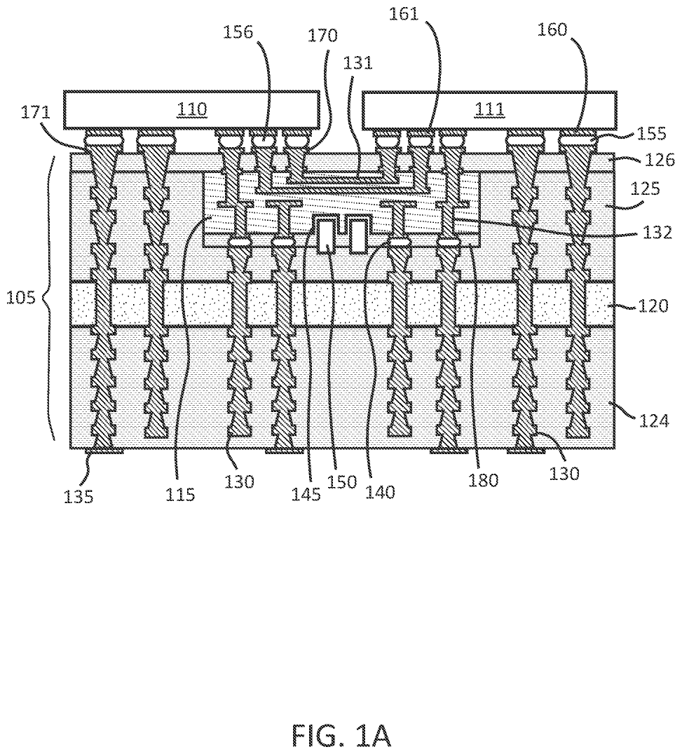

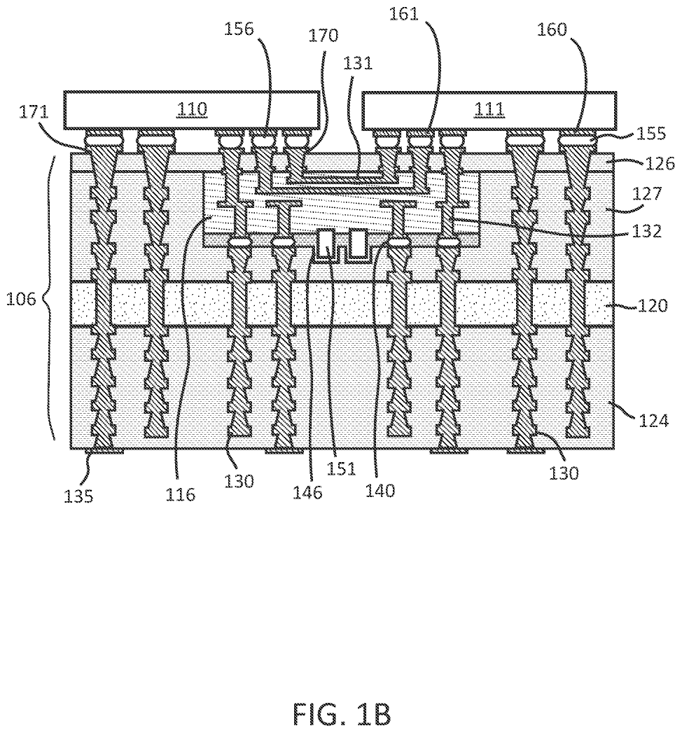

FIGS. 1A-1B show a cross-sectional view of an assembly that includes a package substrate 105 or 106 (respectively) and semiconductor chips 110 and 111. FIGS. 1A-1B illustrate different configurations for alignment features for interconnect bridges 115 and 116 that are embedded in the package substrate 105 or 106. Interconnect bridges 115 and 116 can also be partially embedded or not embedded in the package substrate 105 or 106. In FIG. 1A, package substrate 105 includes interconnect bridge 115. FIG. 1B, package substrate 106 includes interconnect bridge 116. The interconnect bridges 115 and 116 include conductive vias and traces 131 that allow the operably connected semiconductor chips 110 and 111 to communicate with each other. The interconnect bridges 115 and 116 include conductive through-bridge vias (TBVs) 132 that can supply power and the interconnect bridges 115 and 116 can be for example, an EMIB-T. The body of interconnect bridges 115 and 116 can also include a dielectric material as described herein. The package substrates 105 and 106 in these illustrations include a package substrate core 120 which can be an organic core or a glass core as described herein. Package substrates 105 and/or 106 can also be coreless package substrates and package substrate core 120 is optional. Additionally, the package substrates 105 and 106 can have dielectric regions 124, 125 (or 127), and 126 which can be one or more layers of dielectric (such as build-up layers) having conductive traces and vias 130 and board-side pads 135. Board-side pads 135 can connect to a board (e.g., a motherboard, a PCB, a system board, a logic board, or a main board). Connection to a board can be through, for example, solder joints, pins, pads, and/or bumps. The conductive traces and vias 130 can be, for example, comprised of copper.

The interconnect bridge 115 is connected to a subset of the conductive traces and vias 130 through conductive interconnections 140 which can be, for example, comprised of solder. The solder can be, for example, a tin-based alloy that optionally includes silver. Semiconductor chips 110 and 111 have interconnect regions (for first level interconnects (FLI)) 160 and 161 that are operably connected to semiconductor package 105 through semiconductor package FLI regions 171 and EIB FLI regions 170. The conductive interconnections 155 and 156 can be solder, that can be, for example, a tin-based alloy that optionally includes silver. Additionally, the conductive interconnections 155 and 156 can be solderless interconnections between the semiconductor chip FLI regions 160 and 161 and the package substrate FLI regions 170 and 171, respectively. These interconnects can be formed, for example, through a thermocompression bonding process.

The interconnect bridge 115 includes alignment feature receiving cavities 145 into which alignment features 150 have been placed. Alignment features 150 are protrusions. FIG. 1B illustrates an additional example of an interconnect bridge 116 that has alignment features 146. Package substrate 106 includes receiving cavities 146 for alignment features 151. Alignment features 151 are protrusions. Alignment features 150 and 151 can be formed during the package substrate manufacturing process and can be comprised of, for example, a metal, such as, for example, copper or nickel, an alloy of metals, a semiconductor, such as silicon, or an insulating material. Alignment features 150 and 151 can aid in aligning the conductive vias 132 of the interconnect bridge 115 (or 116) with package substate 105 (or 106) conductive vias 130 during manufacture. Although two alignment features are shown in FIGS. 1A and 1B, other numbers of alignment features 150 or 151 are possible, such as for example, one, three, four, or more in a package substrate assembly having an interconnect bridge 115 (or 116). Additionally, alignment features 150 or 151 and receiving cavities 145 and 146, respectively, can have other shapes that are compatible with receiving alignment features 150 or 151. Alignment features 150 and 151 can be, for example, protrusions in the shape of cylindrical pillars, bumps, pyramids, cones, or cuboids.

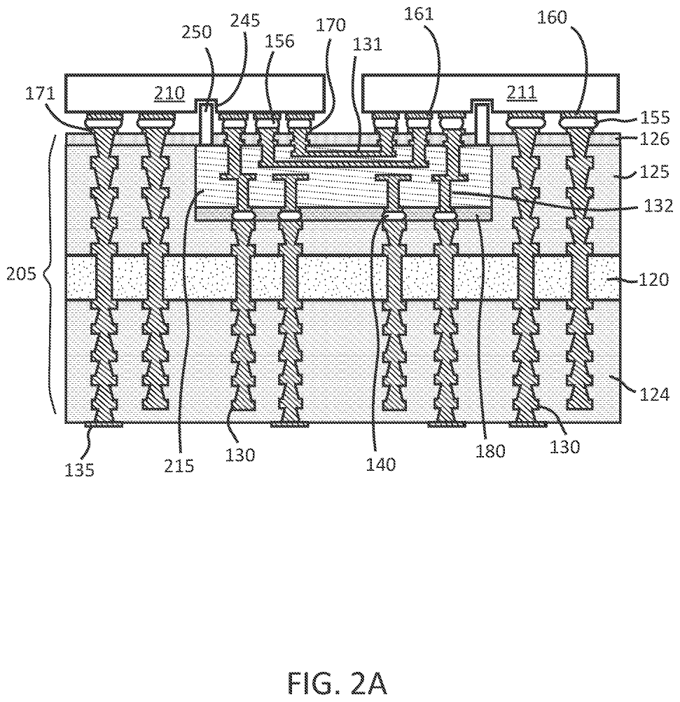

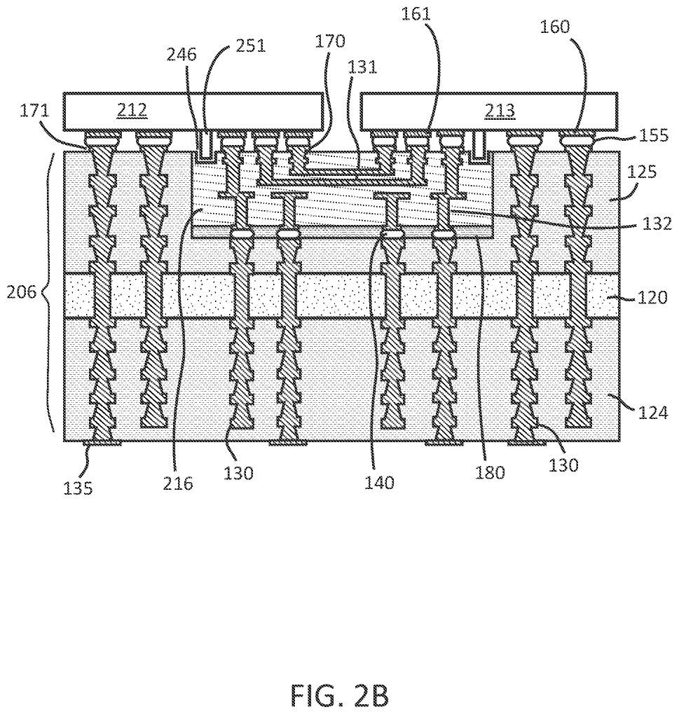

FIGS. 2A and 2B illustrate additional semiconductor package chip assemblies. Where features of FIGS. 2A-2B have the same numbers as features in FIGS. 1A-1B, descriptions herein for those features with respect to FIGS. 1A-1B can also be used for FIGS. 2A-2B. The assembly of FIG. 2A includes semiconductor package substrate 205 and operably connected semiconductor chips 210 and 211. An interconnect bridge 215 includes alignment features 250 that are in receiving cavities 245 in semiconductor chips 210 and 211. FIG. 2B illustrates an additional example of a package substrate 206 that includes an interconnect bridge 216 that has receiving cavities 246 for alignment features 251. Alignment features 250 and 251 are protrusions. Alignment features 250 and 251 can be comprised of, for example, a metal such as copper or nickel, an alloy of metals, a semiconductor, such as silicon, or an insulating material. Alignment features 250 and 251 can aid in aligning semiconductor chip FLIs 161 and 160 with the interconnect bridge 215 (or 216) FLI regions 170 and with package substrate 105 FLI regions 171. Although two alignment features are shown in FIGS. 2A and 2B, other numbers of alignment features 250 or 251 are possible, such as for example, one, three, four, or more in a package substrate assembly having an interconnect bridge 215 (or 216). Additionally, alignment features 250 or 251 and receiving cavities 245 and 246, respectively, can have other shapes that are compatible with receiving alignment features 250 or 251. Alignment features 250 and 251 can be, for example, protrusions in the shape of cylindrical pillars, bumps, pyramids, cones, or cuboids.

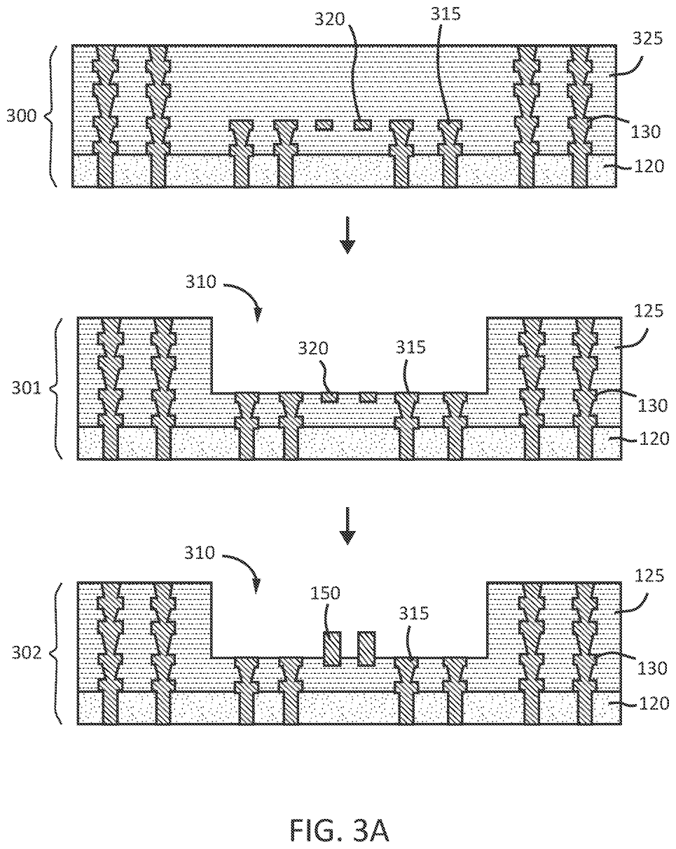

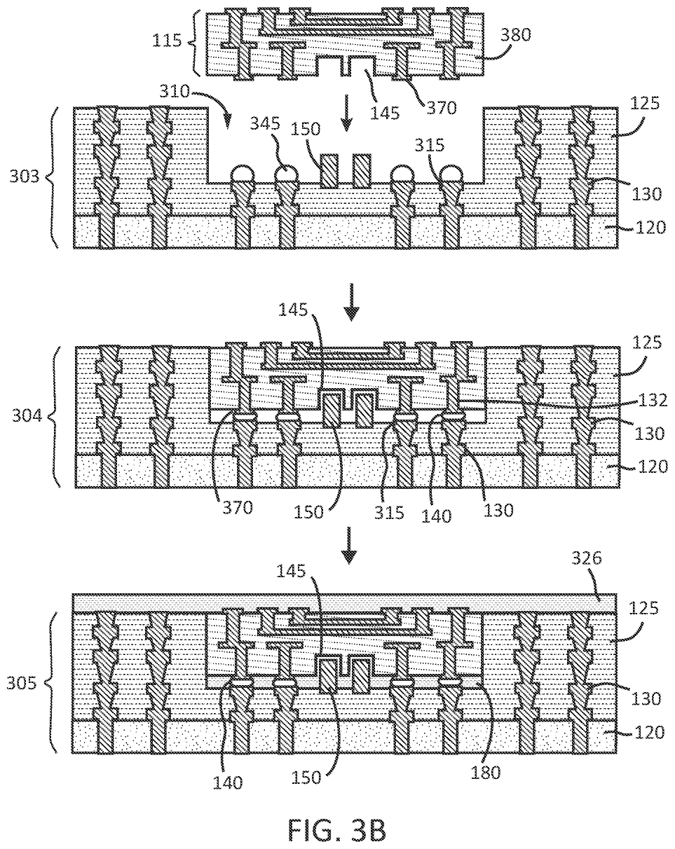

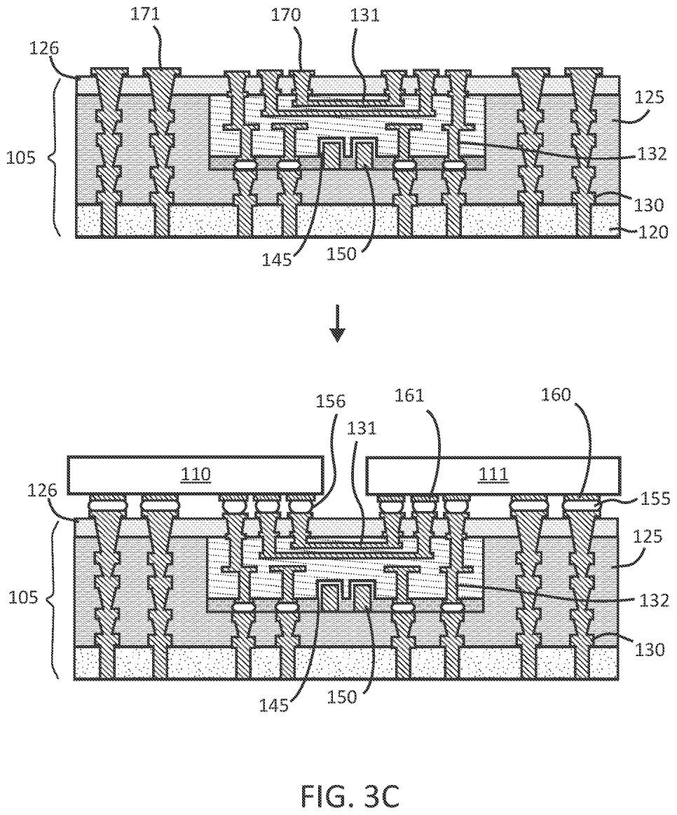

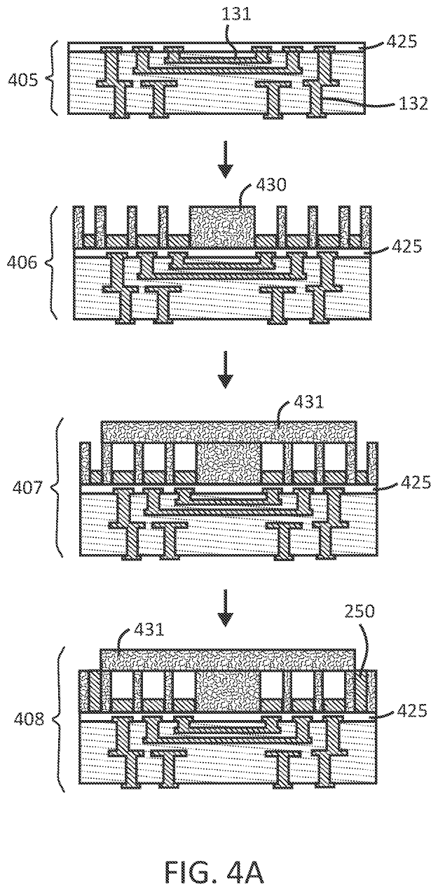

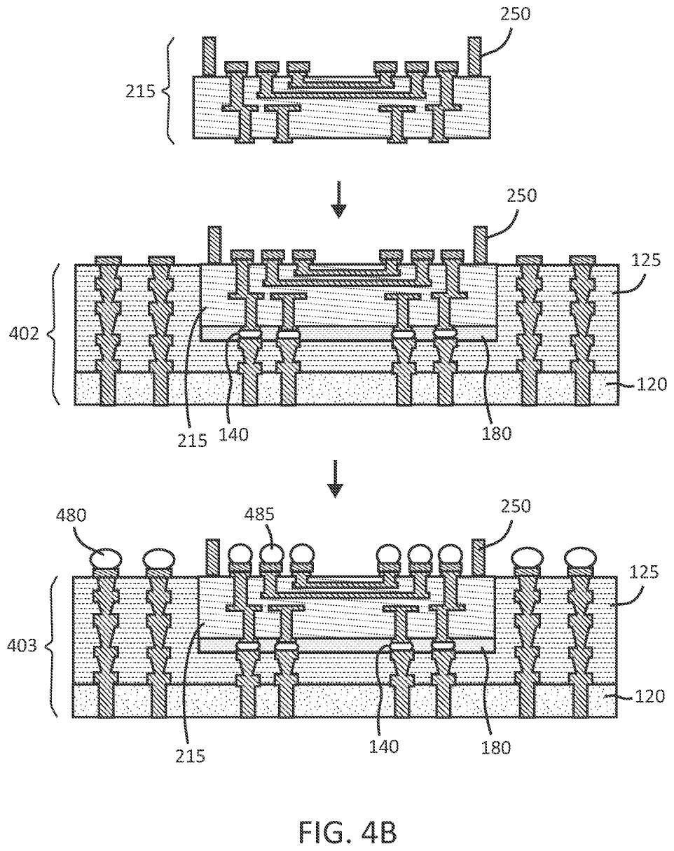

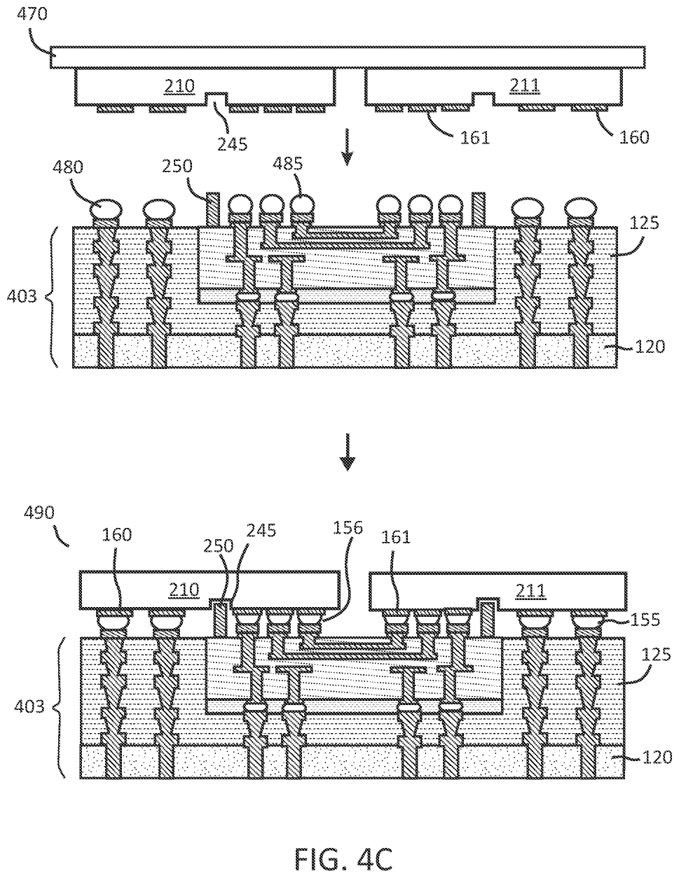

FIGS. 3A-3C illustrate an exemplary method for manufacturing a semiconductor package substrate and a semiconductor package substrate assembly that includes semiconductor chips. Other methods or modifications to these methods are possible. Where features of FIGS. 3A-3C have the same numbers as features in FIGS. 1A-1B, descriptions herein for those features with respect to FIGS. 1A-1B can also be used for FIGS. 3A-3C. In FIG. 3A, a section of a partially manufactured package substrate 300 (which can be, for example, a package substrate of FIG. 1A) is illustrated as including a semiconductor package core 120 (the semiconductor package core 120 is shown in part). The partially manufactured semiconductor package substrate 300 can also be a coreless package substrate. The partially manufactured semiconductor package substrate 300 includes a dielectric region 325 which can comprise layers of dielectric material. A laser cavity drill process creates cavity 310 in partially manufactured package substrate 300 creating partially manufactured package substrate 301. The laser cavity drill process exposes interconnect bridge package landing pads 315 and alignment feature regions 320. Partially manufactured package substrate 302 is created by depositing a photoresist onto a surface (that has exposed interconnect bridge package landing pads 315 and alignment feature regions 320) of cavity 310, lithographically patterning the photoresist to create a mast that provides an unmasked region for electrodeposition of a metal into the cavities forming alignment features 150 (see, for example, FIGS. 4A-4B where a similar process for forming alignment features is illustrated in more detail). Alignment features 150 can be protrusions comprised of one or more metals, such as, for example, copper and/or nickel.

In FIG. 3B, an interconnect bridge 115 is placed into cavity 310 of partially manufactured package substrate 303, creating partially manufactured package substrate 304. Solder bumps 345 have been added to the interconnect bridge-side package landing pads 315, although, solder could also be placed on package-side landing pads 370 of interconnect bridge 115. Solder bumps (balls or regions) can be formed, for example, through a plating method where a seed layer is formed, a photoresist is lithographically patterned to create the solder region mask, solder is plated, the photoresist is removed, the seed layer is etched, and the solder is reflowed to create a bump (or ball shape). Other methods are possible. Interconnect bridge 115 includes alignment feature receiving cavities 145 in dielectric material 380 which can be created through an etching process, such as, for example, pulsed or time-multiplexed etching. A solder reflow process creates electrical interconnections 140 between the interconnect bridge-side package landing pads 315 of partially manufactured package substrate 304 and package-side landing pads 370 of interconnect bridge 115. Dielectric underfill material 180 is added between the interconnect bridge 115 and the partially manufactured package substrate 304. A dielectric layer 326 is deposited on a surface of the partially manufactured package substrate 304, creating partially manufactured package substrate 305. The dielectric layer 326, can be, for example, ABF.

In FIG. 3C, the dielectric layer 326 of partially manufactured package substrate 305 has been patterned for vias (forming dielectric layer 126), metal deposited into vias, and landing pads 170 and 171 created, yielding package substrate 105. Solder regions are added to either the semiconductor package substrate or the incoming semiconductor chips 110 or 111, to form interconnections 155. Alternatively, bonding can be accomplished through a thermocompression bonding process.

FIGS. 4A-4C illustrate an exemplary method for manufacturing a semiconductor package substrate and a semiconductor package substrate assembly that includes semiconductor chips. Other methods or modifications to these methods are possible. Where features of FIGS. 4A-4C have the same numbers as features in FIGS. 1A-1B, descriptions herein for those features with respect to FIGS. 1A-1B can also be used for FIGS. 4A-4C. In FIG. 4A, a partially formed interconnect bridge 405 includes a titanium/copper layer 425 of on a surface. A photoresist material 430 is coated on the surface, lithographically patterned, and metal is deposited, forming partially formed interconnect bridge 406. A second layer of photoresist material 431 is deposited and lithographically patterned, creating partially formed interconnect bridge 407. The resist material 430 and 431 can be applied to the interconnect bridge surface through, for example, a spin-on process. Additional metal is deposited forming alignment features 250 in partially formed interconnect bridge 408. Metal deposition can be, for example, an electrodeposition process.

In FIG. 4B, the photoresist has been removed from partially formed interconnect bridge 408 and the titanium/copper layer 425 is removed creating interconnect bridge 215. The titanium/copper layer 425 can be removed, for example, through etching. Interconnect bridge 215 is placed into a receiving cavity of a package substrate (see, for example, receiving cavity 310 of FIG. 3A), for example, through a pick and place process. Solder regions (that are either originally on either the package substrate or the interconnect bridge 215 are reflowed to create interconnections 140 and dielectric underfill material 180 is flowed into the region between the interconnect bridge 215 and the package substrate creating package substrate 402. Solder bumps 480 and 485 are formed on the FLI regions of the package substrate 402 forming package substrate 403. Solder bumps can be formed, for example, through a plating process where a seed layer is formed, a photoresist is lithographically patterned to create the solder region mask, solder is plated, the photoresist is removed, the seed layer is etched, and the solder is reflowed to create a bump. Other methods are also possible. Solder bumps can also alternatively be on the FLI landing pads 160 and 161 semiconductor chips 210 and 211. Semiconductor chips 210 and 211 can be attached to a removable carrier 470 for the attachment process. Semiconductor chips 210 and 211 have receiving cavities 245 for alignment features 250. Alignment feature receiving cavities 245 can be created through an etching process, such as, for example, pulsed or time-multiplexed etching. Attachment of semiconductor chips 210 and 211 to package substrate 403 creates assembly 490. A solder reflow process creates conductive interconnects 155 and 156.

Additional assemblies, such as those of FIG. 1B and FIG. 2B, can be created using similar methods as described herein with modifications. For example, alignment features 151 on interconnect bridge 116 can be created in a manner similar to the creation of alignment features 150 on package substrate 105. Alignment feature receiving cavities 146 in package substrate 106 can be created, for example, using a pulsed or time-multiplexed etching process. Additionally, alignment features 251 on semiconductor chips 212 and 213 can be created in a manner similar to the creation of alignment features 250 on package substrate 205. Alignment feature receiving cavities 246 in interconnect bridge 216 can be created, for example, using a pulsed or time-multiplexed etching process.

The assemblies of FIGS. 1A-1B, 2A-2B, 3A-3C, and 4A-4C are provided for illustrative purposes and package substrates and assemblies can include, for example, other numbers of layers, traces and vias, and semiconductor chips.

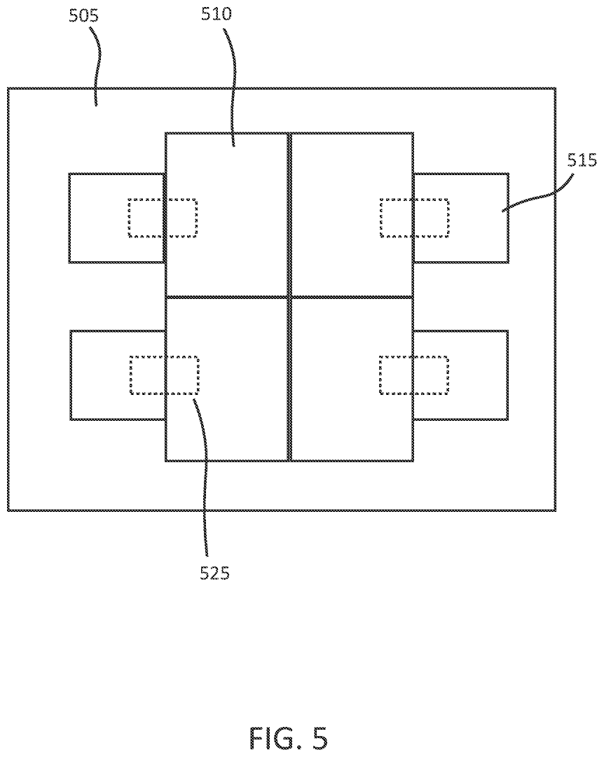

FIG. 5 shows an exemplary configuration for packaged semiconductor chips mounted on a board. Many other configurations are possible. In FIG. 5, a board 505 (e.g., a motherboard, a printed circuit board, a system board, a logic board, a circuit board, or a main board) has packaged semiconductor chips 510 and 515 operably coupled to the board 505. Interconnect bridges 525 are shown with a dashed line and are covered by packaged semiconductor chips 510 and 515 in this view. The interconnect bridges 525 can be more than one interconnect bridge, can be interconnect bridges that are with or without TBVs, and the semiconductor chip package substrates can contain more than one type of interconnect bridge. The interconnect bridges can be mounted in the package substrate as described herein with respect to FIGS. 1, 2A-2C, and 3A-3C. For example, one or more chips 510 can be a processor or a field programmable gate array (FPGA), and one or more of the chips 515 can be a HBM die stack and/or and one or more of the chips 515 can be a transceiver chip.

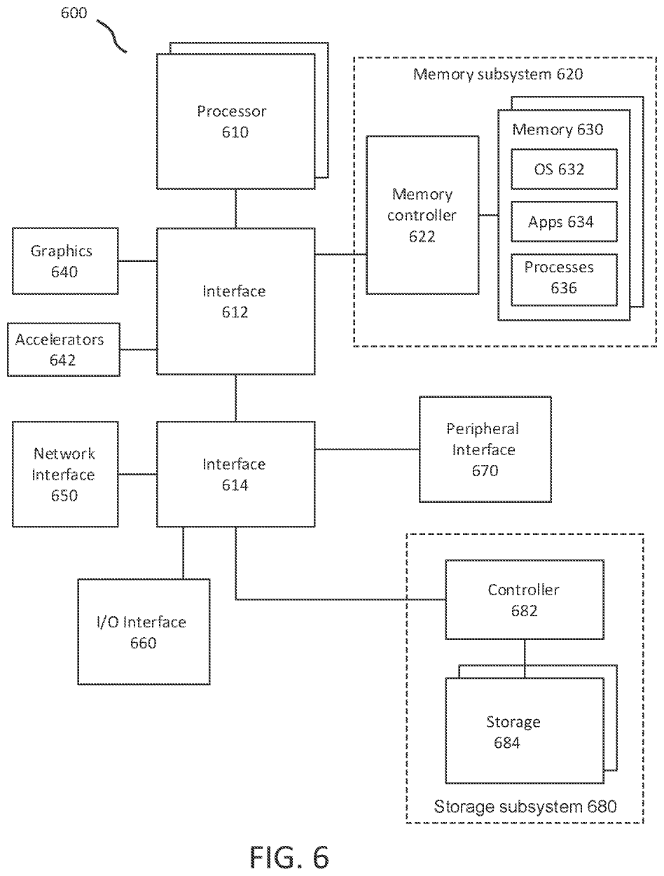

The semiconductor chips 110, 111, 210, 211, 212, 213, 510, and 515 can be, for example, any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM die stacks, and/or other memory devices. The semiconductor chips 110, 111, 210, 211, 212, 213, 510, and 515 can be any of the chips, for example, described herein with respect to FIG. 6. The interconnect bridge assemblies described herein generally can be used between semiconductor chips in various package configurations and the foregoing examples are not meant to limit the types of assemblies that are possible.

FIG. 6 depicts an example computing system. The computing system can be a system used for running equipment in a semiconductor fabrication plant. For example, instructions for operating semiconductor processing equipment or for performing one or more aspects of the process described in FIGS. 3A-3C and 4A-4C can be stored and/or run on the computing system. A computing system 600 can include more, different, or fewer features than the ones described with respect to FIG. 6.

Computing system 600 includes processor 610, which provides processing, operation management, and execution of instructions for system 600. Processor 610 can include any type of microprocessor, CPU (central processing unit), GPU (graphics processing unit), processing core, or other processing hardware to provide processing for system 600, or a combination of processors or processing cores. Processor 610 controls the overall operation of system 600, and can be or include, one or more programmable general-purpose or special-purpose microprocessors, DSPs, programmable controllers, ASICs, programmable logic devices (PLDs), or the like, or a combination of such devices.

In one example, system 600 includes interface 612 coupled to processor 610, which can represent a higher speed interface or a high throughput interface for system components needing higher bandwidth connections, such as memory subsystem 620 or graphics interface components 640, and/or accelerators 642. Interface 612 represents an interface circuit, which can be a standalone component or integrated onto a processor die. Where present, graphics interface 640 interfaces to graphics components for providing a visual display to a user of system 600. In one example, the display can include a touchscreen display.

Accelerators 642 can be a fixed function or programmable offload engine that can be accessed or used by a processor 610. For example, an accelerator among accelerators 642 can provide data compression (DC) capability, cryptography services such as public key encryption (PKE), cipher, hash/authentication capabilities, decryption, or other capabilities or services. In some cases, accelerators 642 can be integrated into a CPU socket (e.g., a connector to a motherboard (or circuit board, printed circuit board, mainboard, system board, or logic board) that includes a CPU and provides an electrical interface with the CPU). For example, accelerators 642 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 642 can provide multiple neural networks, CPUs, processor cores, general purpose graphics processing units, or graphics processing units can be made available for use by artificial intelligence (AI) or machine learning (ML) models.

Memory subsystem 620 represents the main memory of system 600 and provides storage for code to be executed by processor 610, or data values to be used in executing a routine. Memory subsystem 620 can include one or more memory devices 630 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 630 stores and hosts, among other things, operating system (OS) 632 that provides a software platform for execution of instructions in system 600, and stores and hosts applications 634 and processes 636. In one example, memory subsystem 620 includes memory controller 622, which is a memory controller to generate and issue commands to memory 630. The memory controller 622 can be a physical part of processor 610 or a physical part of interface 612. For example, memory controller 622 can be an integrated memory controller, integrated onto a circuit within processor 610.

System 600 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 600 includes interface 614, which can be coupled to interface 612. In one example, interface 614 represents an interface circuit, which can include standalone components and integrated circuitry. In one example, user interface components or peripheral components, or both, couple to interface 614. Network interface 650 provides system 600 the ability to communicate with remote devices (e.g., servers or other computing devices) over one or more networks. Network interface 650 can include an Ethernet adapter, wireless interconnection components, cellular network interconnection components, USB, or other wired or wireless standards-based or proprietary interfaces. Network interface 650 can transmit data to a device that is in the same data center or rack or a remote device, which can include sending data stored in memory.

Some examples of network interface 650 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 600 includes one or more input/output (I/O) interface(s) 660. I/O interface 660 can include one or more interface components through which a user interacts with system 600 (e.g., audio, alphanumeric, tactile/touch, or other interfacing). Peripheral interface 670 can include additional types of hardware interfaces, such as, for example, interfaces to semiconductor fabrication equipment and/or electrostatic charge management devices.

In one example, system 600 includes storage subsystem 680. Storage subsystem 680 includes storage device(s) 684, which can be or include any conventional medium for storing data in a nonvolatile manner, such as one or more magnetic, solid state, and/or optical based disks. Storage 684 can be generically considered to be a “memory,” although memory 630 is typically the executing or operating memory to provide instructions to processor 610. Whereas storage 684 is nonvolatile, memory 630 can include volatile memory (e.g., the value or state of the data is indeterminate if power is interrupted to system 600). In one example, storage subsystem 680 includes controller 682 to interface with storage 684. In one example controller 682 is a physical part of interface 612 or processor 610 or can include circuits or logic in both processor 610 and interface 614.

A power source (not depicted) provides power to the components of system 600. More specifically, power source typically interfaces to one or multiple power supplies in system 600 to provide power to the components of system 600.

Exemplary systems may be implemented in various types of computing, smart phones, tablets, personal computers, and networking equipment, such as switches, routers, racks, and blade servers such as those employed in a data center and/or server farm environment.

### EXAMPLES

An apparatus comprises: a substrate; an interconnect bridge on the substrate wherein the interconnect bridge includes conductive traces and conductive through-bridge vias, wherein the interconnect bridge has a cavity; and a protrusion on the substrate wherein the protrusion extends into the cavity of the interconnect bridge. The protrusion can be comprised of a metal or silicon. The protrusion can be comprised of copper. The protrusion can have a cylindrical pillar, a bump, a pyramid, a cone, or a cuboid shape. There can be two or more protrusions and two or more protrusion receiving cavities, wherein a first protrusion of the two or more protrusions extends into a first protrusion receiving cavity of the two or more protrusion receiving cavities and a second protrusion of the two or more protrusions extends into a second protrusion receiving cavity of the two or more protrusion receiving cavities. The substrate can be a coreless semiconductor package substrate. The apparatus can also include a package substrate core that can be comprised of glass or an organic material. The apparatus can also include a package substrate core that can be a solid amorphous glass material that is comprised of aluminosilicate, borosilicate, alumino-borosilicate, silica, or fused silica.

An apparatus can comprise: a first semiconductor chip wherein the first semiconductor chip comprises a protrusion receiving cavity; and a substrate wherein the substrate comprises: an interconnect bridge wherein the interconnect bridge includes metallic traces and metallic through-bridge vias, wherein the interconnect bridge has a protrusion, wherein the protrusion extends into the protrusion receiving cavity of the first semiconductor chip. The protrusion can be comprised of a metal or silicon. The protrusion can be comprised of copper, nickel, or a combination thereof. The protrusion can have a cylindrical pillar, a bump, a pyramid, a cone, or a cuboid shape. The apparatus can also include a second semiconductor chip wherein the second semiconductor chip can be communicatively coupled to the first semiconductor chip through the interconnect bridge. The apparatus can also include a circuit board, wherein the substrate is operably coupled to the circuit board, wherein the circuit board comprises a power supply, and wherein the power supply is capable of providing power to the first semiconductor chip through the interconnect bridge.

A method of manufacturing an apparatus can comprise: creating a cavity in a partially manufactured substrate to expose interconnect bridge-side landing pads and protrusion regions within the partially manufactured substrate; creating protrusions on the protrusion regions; placing an interconnect bridge into the cavity wherein the interconnect bridge comprises protrusion receiving cavities, wherein the interconnect bridge comprises landing pads, and wherein a protrusion extends into a protrusion cavity; and reflowing a solder material to create metallic interconnections between the interconnect bridge-side landing pads and the interconnect bridge landing pads. The protrusions can be comprised of copper, nickel, or a combination thereof. The protrusions can be created through a metal deposition process. The method of manufacturing an apparatus can also include flowing an underfill material between the interconnect bridge and a side of the cavity in a partially manufactured substrate. The method of manufacturing an apparatus can also include placing solder on the interconnect bridge-side landing pads. The interconnect bridge landing pads can comprise solder bumps.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus comprising:
a substrate;
an interconnect bridge on the substrate wherein the interconnect bridge includes conductive traces and conductive through-bridge vias, wherein the interconnect bridge has a cavity; and
a protrusion on the substrate wherein the protrusion extends into the cavity of the interconnect bridge.

2. The apparatus of claim 1 wherein the protrusion is comprised of a metal or silicon.

3. The apparatus of claim 1 wherein the protrusion is comprised of copper.

4. The apparatus of claim 1 wherein the protrusion has a cylindrical pillar, a bump, a pyramid, a cone, or a cuboid shape.

5. The apparatus of claim 1 wherein there are two or more protrusions and two or more protrusion receiving cavities and wherein a first protrusion of the two or more protrusions extends into a first protrusion receiving cavity of the two or more protrusion receiving cavities and a second protrusion of the two or more protrusions extends into a second protrusion receiving cavity of the two or more protrusion receiving cavities.

6. The apparatus of claim 1 wherein the substrate is a coreless semiconductor package substrate.

7. The apparatus of claim 1 also including a package substrate core that is comprised of glass or an organic material.

8. The apparatus of claim 1 also including a package substrate core that is a solid amorphous glass material that is comprised of aluminosilicate, borosilicate, alumino-borosilicate, silica, or fused silica.

9. An apparatus comprising:
a first semiconductor chip wherein the first semiconductor chip comprises a protrusion receiving cavity; and
a substrate wherein the substrate comprises:
an interconnect bridge wherein the interconnect bridge includes metallic traces and metallic through-bridge vias, wherein the interconnect bridge has a protrusion, wherein the protrusion extends into the protrusion receiving cavity of the first semiconductor chip.

10. The apparatus of claim 9 wherein the protrusion is comprised of a metal or silicon.

11. The apparatus of claim 9 wherein the protrusion is comprised of copper, nickel, or a combination thereof.

12. The apparatus of claim 9 wherein the protrusion has a cylindrical pillar, a bump, a pyramid, a cone, or a cuboid shape.

13. The apparatus of claim 9 also including a second semiconductor chip wherein the second semiconductor chip is communicatively coupled to the first semiconductor chip through the interconnect bridge.

14. The apparatus of claim 9 also including a circuit board, wherein the substrate is operably coupled to the circuit board, wherein the circuit board comprises a power supply, and wherein the power supply is capable of providing power to the first semiconductor chip through the interconnect bridge.

15. A method of manufacturing an apparatus comprising:
creating a cavity in a partially manufactured substrate to expose interconnect bridge-side landing pads and protrusion regions within the partially manufactured substrate;
creating protrusions on the protrusion regions;
placing an interconnect bridge into the cavity wherein the interconnect bridge comprises protrusion receiving cavities, wherein the interconnect bridge comprises landing pads, and wherein a protrusion extends into a protrusion cavity; and
reflowing a solder material to create metallic interconnections between the interconnect bridge-side landing pads and the interconnect bridge landing pads.

16. The method of manufacturing an apparatus of claim 15 wherein the protrusions are comprised of copper, nickel, or a combination thereof.

17. The method of manufacturing an apparatus of claim 15 wherein the protrusions are created through a metal deposition process.

18. The method of manufacturing an apparatus of claim 15 also including flowing an underfill material between the interconnect bridge and a side of the cavity in a partially manufactured substrate.

19. The method of manufacturing an apparatus of claim 15 also including placing solder on the interconnect bridge-side landing pads.

20. The method of manufacturing an apparatus of claim 15 wherein the interconnect bridge landing pads comprise solder bumps.
